(19) United States
(12) Patent Application Publication
(10) Pub. No.: US 2010/0044675 A1
(43) Pub. Date: Feb. 25, 2010

(54) Photovoltaic Device With an Up-Converting Quantum Dot Layer

(75) Inventors: Hans Jurgen Richter, Palo Alto, CA (US); Samuel Dacke Harkness, IV, Berkeley, CA (US)

Correspondence Address: PIETRAGALLO GORDON ALFANO BOSICK & RASPANTI, LLP, ONE OXFORD CENTRE, 38TH FLOOR, 301 GRANT STREET, PITTSBURGH, PA, 15219-6404, US

(73) Assignee: Seagate Technology LLC, Scotts Valley, CA (US)

(21) Appl. No.: 12/195,520

(22) Filed: Aug. 21, 2008

(51) Int. Cl. H01L 29/06; H01L 31/0248

(52) U.S. Cl. 257/14; 257/431; 257/E31.004; 257/E31.052; 257/E29.168

(57) ABSTRACT

A photovoltaic apparatus includes an absorber layer, and an up-converter layer positioned adjacent to the absorber layer, the up-converter layer including a plurality of quantum dots of first material in a matrix of a second material. In one example, the first material has a lower bandgap than the absorber layer, and the second material comprises a semiconductive material or an insulator.

### BACKGROUND

Photovoltaic devices, also referred to as solar cells, convert light directly into electricity. The majority of photovoltaic devices use a semiconductor as an absorber layer with a well-defined bandgap, such as crystalline silicon having an energy bandgap E_{g} of 1.1 eV. Photovoltaic devices include layers of semiconductor materials with different electronic properties. One of the layers of silicon can be “doped” with a small quantity of boron to give it a positive (or p-type) character. Another layer can be doped with phosphorus to give it a negative (or n-type) character. The p and n regions can be adjacent to each other or separated by an intermediate layer. The interface, or junction, between these two layers contains an electric field.

When light (i.e., photons) hits the device, some of the photons are absorbed in the region of the junction, creating electron-hole pairs and freeing electrons and holes (i.e., carriers) in the silicon crystal. If the photons have enough energy, the carriers will be driven out by the electric field and move through the silicon and into an external circuit.

Light with energy lower than the bandgap is not absorbed and is thus lost for photoelectric conversion. Light with energy E greater than the bandgap E_{g} is absorbed. However, the excess energy E-E_{g} is lost due to thermalization. It is well known that this results in an optimum choice for the bandgap of the absorber material. Invoking the principle of detailed balance, the optimum bandgap of a photovoltaic device has been found to be about 1.4 eV with a limiting conversion efficiency of 33%.

In single bandgap cells, only a fraction of the energy spectrum of the incident light is used for the energy conversion. For example, only a part of the energy of incident sunlight is available for photo conversion.

In the literature, several approaches to increase the utilization of the solar spectrum have been suggested. One approach is to construct the photovoltaic device out of a series of layers with different bandgap materials, where each layer reacts to a different portion of the solar spectrum. Another approach is to use the principle of multiple carrier generation, wherein light with high energy creates more than one electron per incoming photon, such that the thermalization losses are reduced.

Yet another approach is to employ “Intermediate Level Cells,” in which a material with an additional electronic band (i.e., an intermediate band) is located in the energy gap between the valence band and the conduction band. Then absorption can occur from the valence band to the intermediate band, from the intermediate band to the conduction band, and from the valence band to the conduction band.

A variation of the intermediate bandgap cell is to use up-conversion or down-conversion of photons. In cells having a down-converter, a down-converter layer reduces the energy of the high energy fraction of the incident light before it passes to the absorber.

In cells having an up-converter, a part of the light energy with E>E_{g} that enters the structure is absorbed in the usual way. The low energy portion of the light (i.e., where E<E_{g}) goes through the absorber with essentially no attenuation. In the up-converter, the photons are absorbed in two or more steps. After excitation, the electron-hole pairs recombine radiatively in one step, whereby they emit light of correspondingly higher energy. This emitted light is directed back to the absorber. In a properly designed system, the energy of the emitted light is greater than the absorber bandgap and the solar cell absorber has an opportunity to absorb energy of the lower energy part of the spectrum. The theoretical limit for the efficiency of an up-converting cell is 47.6%. In the literature, it has been suggested to use Erbium doped NaYF₄ as up-converting material, but the reported quantum efficiencies were very poor.

### SUMMARY

In one aspect, the invention provides a photovoltaic apparatus including an absorber layer, and an up-converter layer positioned adjacent to the absorber layer, the up-converter layer including a plurality of quantum dots of first material in a matrix of a second material. In one example, the first material has a lower bandgap than the absorber layer, and the second material comprises a semiconductive material or an insulator.

### BRIEF DESCRIPTION OF THE DRAWINGS

FIG. 1 is a schematic elevation view of a photovoltaic device constructed in accordance with a first aspect of the invention.

FIG. 2 is a schematic representation of energy levels in the device of FIG. 1.

FIG. 3 is a schematic elevation view of a photovoltaic device constructed in accordance with another aspect of the invention.

### DETAILED DESCRIPTION OF THE INVENTION

In one aspect, this invention provides a photovoltaic device that uses a quantum dot layer as a means for up-converting light. The quantum dot layer can be located underneath the absorber layer. Low energy light that passes through the absorber layer is up-converted and emitted back to the absorber by the quantum dot layer, thus enhancing the conversion efficiency of the device.

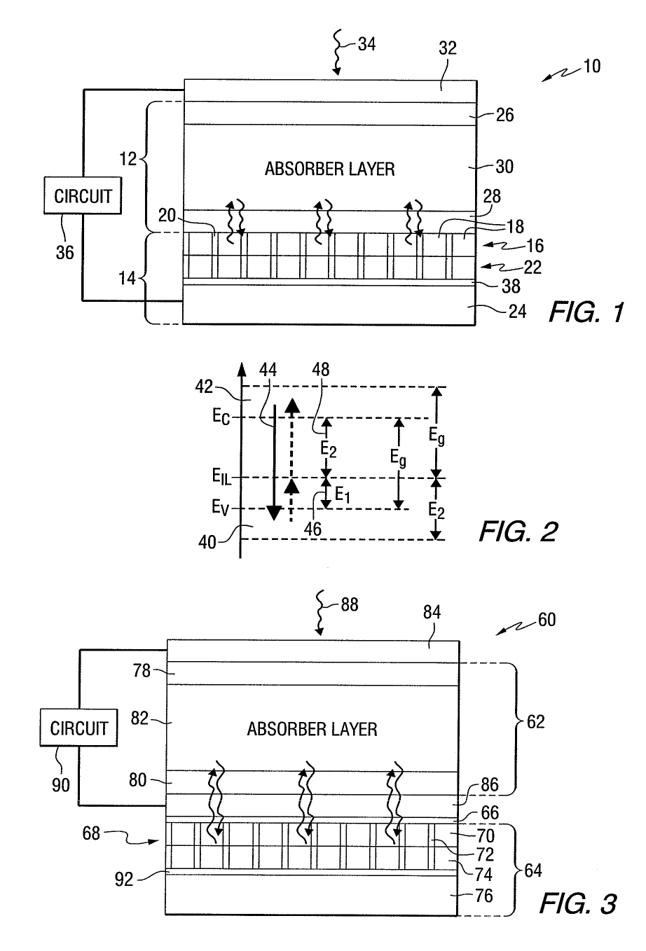

FIG. 1 is a schematic representation of a photovoltaic device 10 including an absorber 12, and an up-converter 14 positioned adjacent to the absorber, constructed in accordance with one aspect of the invention.

The up-converter layer includes a quantum dot layer 16, which includes a plurality of quantum dots 18 of a semiconductive material. The quantum dots are separated by a wide bandgap semiconductor material or an insulating material 20, such as for example, TiO₂ or SiO₂. The quantum dots can be formed on a seedlayer 22 that is supported by a substrate 24, which can be an amorphous metal. The substrate can also serve as a reflector. Underneath the seedlayer is an amorphous layer 38, which is continuous. While in principle the amorphous layer could be the substrate, in practice the amorphous layer 38 is deposited in a separate step.

The absorber includes a p-doped region 26 and an n-doped region 28. These regions can be formed in a material such as silicon. An optional intermediate layer 30 is positioned between the p and n regions. The absorber in this example forms a p-i-n diode. The interface, or junction, between the p and n regions contains an electric field. A transparent conductive oxide (TCO) electrode 32 is formed on top of the absorber. When light 34 (i.e., photons) hits the device, some of the photons are absorbed in the region of the junction, freeing electrons and holes in the absorber. If the photons have enough energy, the carriers will be driven out by the electric field and move through the absorber and into an external circuit 36. In this example, the TCO electrode and the substrate serve as means for connecting the device to an external circuit.

FIG. 2 is a schematic representation of energy levels in the device of FIG. 1. E_{g} is the energy gap between the valence band 40 and the conduction band 42 for the absorber material. E_{V} represents the energy level at the top of the valence band, E_{C} represents the energy level at the bottom of the conduction band, and E_{IL} represents an intermediate energy level. The low energy portion of the light (i.e., where E<E_{g}) goes through the absorber with essentially no attenuation. In the up-converter, the photons are absorbed in two or more steps. In this example, E₁ is the difference in energy between E_{V} and E_{IL}, and E₂ is the difference in energy between E_{IL} and E_{C}. After excitation, the electron-hole pairs recombine radiatively in one step as illustrated by arrow 44, whereby they emit light of correspondingly higher energy Eₑₘᵢₜ=E₁+E₂, as illustrated by arrows 46 and 48. This emitted light is directed back to the absorber, either directly or by being reflected by the reflector.

The utilization of quantum dots as an up-converter has the advantage that quantum dots provide a strong absorption and allow an easy way to control the energy levels, such as by changing the dot size. The quantum dots can be grown on suitable templates, which may be metallic in nature, that exhibit the ability to induce crystallographic texture in the semiconductor layer above. An example of a template that can be used to grow the quantum dots is described in a commonly owned U.S. patent application, filed on the same date as this application and titled “Thin Film Template For Fabrication Of Two-Dimensional Quantum Dot Structures”, which is hereby incorporated by reference.

The up-conversion layer can be in the form of a two-dimensional sheet film structure that includes a matrix containing co-planar precipitates of quantum dot (QD) semiconductors. This configuration yields a very high coverage of the seedlayer surface with quantum dots enabling high optical absorption. Examples of the fabrication of the quantum dot layer are described below.

The semiconductor material that is used to form the quantum dots can be co-deposited with a second material, for example a wide bandgap semiconductor material or insulating material, such that the quantum dots nucleate as a precipitate in a matrix material. The volume fraction of the quantum dot material can be between about 40% and about 90%. The quantum dot material can be, for example, PbS, PbSe, InAs, InP, InN, InSb, CdS, CdSe, CdTe, B₂S₃, SiₓGe₁₋ₓ, Bi₂S₃, AlSb, or SiₓGe₁₋ₓ. The matrix material can be, for example, TiO₂, SiO₂, ZnS, Ta₂O₅, Zn₂P₃, or Nb₂O₅.

The quantum dots and matrix materials can be fabricated using a sputter deposition technique. The quantum dot layer can be fabricated in a process environment that is similar to the region of a Thornton Diagram known as Zone 1. Process conditions typical to the Thornton Diagram Zone 1 are low to moderate substrate temperatures (e.g., <40% homologous temperature), and relatively high sputter gas pressures (e.g., >20 mTorr).

In one example, the substrate temperature is <200° C. and the gas pressure is >30 mTorr Ar. This process configuration yields thin films with columnar grain structures with varying amounts of porosity between neighboring quantum dots, also referred to as grains. Generally, the quantum dot and matrix materials should have surface energies between 2-3 J/m². Most materials with lower surface energy will tend to wet the surface and most higher will tend toward being amorphous.

Such a process facilitates the segregation of immiscible materials, forming a columnar grain structure of quantum dots, while the immiscible matrix material is collected, or trapped, at the porous grain boundary regions, where it forms a connective matrix with low volume fraction. The quantum dot layer may resemble a honeycomb when viewed in plan view, where the matrix forms the honeycomb lattice and the quantum dots occupy the holes. Examples of suitable matrix materials, also referred to as segregates, include TiO₂, SiO₂, ZnS, Ta₂O₅, or Nb₂O₅.

Depending on the electrical characteristics of the sputter targets used in the deposition process, rf-magnetron or rf-diode cathodes may be used for the deposition. When using PbS for the dot material and TiO₂ for the matrix material, commercially available dc-magnetrons may be used. Dc-magnetrons offer flexibility in terms of processing pressure and may therefore be more desirable to use in a manufacturing setting. It may also be necessary to include the addition of gases such as O₂ or H₂S or others during the co-deposition, so as to properly adjust the constituent stoichiometries of the semiconductor and the segregant. Such a co-deposition process leads to isolated semiconductor grain particles that have dimensions consistent with quantum confinement (e.g., about 2 nm to about 10 nm).

A log-normal distribution of grain diameters, d, can be expected. With optimization, it is possible to achieve σ_{d}/d less than 20%, where σ_{d} is the standard deviation of the grain sizes. In one example, the quantum dot layer thickness can range from about 2 nm to about 20 nm. In another example, the quantum dot layer thickness can range from about 2 nm to about 10 nm.

Suitable materials for the quantum dots include low bandgap materials, such as PbS, PbSe, InP, CdSe, CdS, InAs, InSb, Ge and so forth. The choice of the matrix material is discussed further below.

Some design rules for selecting the materials are as follows:

1. A particle can be considered a quantum dot, if the following relation holds

$$Δ x \approx \sqrt{3} π \sqrt{\frac{{ℏ}^{2}}{{mk}_{B} T}} where$$

=Planck's constant (i.e., approximately 6.626×10⁻³⁴ joule-seconds),

m=the effective electron mass,

k_{B}T=thermal energy,

k_{B}=1.38 10⁻³⁴ J/K, and

T=temperature in Kelvin,

that is, the particle diameter should be equal or less than Δx.

The energy levels in these quantum dots are given by:

$$E = \frac{{π}^{2} {ℏ}^{2}}{2 m} ( \frac{{n}_{x}^{2}}{{d}_{x}^{2}} + \frac{{n}_{y}^{2}}{{d}_{y}^{2}} + \frac{{n}_{z}^{2}}{{d}_{z}^{2}} )$$

where dₓ, d_{y} and d_{z} are the dimensions of the dot in the respective directions and nₓ, n_{y}, and n_{Z} are integers (1, 2, 3, . . . ) and specify the quantization levels. It is therefore clear that a simple control of the size of the dots creates the necessary energy levels needed for an up-conversion process.

2. Materials that are best suited for up-converters are those in which electrons are allowed to relax after one of the intermediate steps, if this relaxation is combined with a change in selection rules for radiative transitions involving the relaxed state and the unrelaxed state, respectively. As stated above, an up-conversion is more likely to occur if there is a two-step process in which the selection rules change.

3. Ideally, the indices of refraction (i.e., the indices of the composite quantum dot and matrix layer) of the absorber and the up-converter should be matched.

As an example, consider a device in which amorphous Si is used as the absorber material. From published data, PbS, PbSe, InAs and Ge are good quantum dot material candidates for fulfilling the requirement that the bandgap is rather small and that the index of refraction in the region of interest (long wavelength) match that of amorphous Si reasonably well.

The quantum dot layer can be grown on a structure having several layers. Suitable growth layers have two or more individual layers where the top layer or seedlayer is used to create the granular structure on which the quantum dots are grown. The seedlayer may include elements such as Al, Au, Ag, Pt, Pd, Cu, Ni, Rh, Ru, Co, Re, Os, Cr, Mo, V, Ta, V and multi-component alloys of the same elements. The seedlayer can be grown on amorphous metallic layers such as FeCoB or CrTa or other such amorphous metals/alloys. The seedlayer and the amorphous metallic layer can form a reflector that is used to reflect photons back to the absorber. Typical dot sizes are between about 5 nm and about 12 nm, with a thickness ranging from about 10 nm to about 50 nm. The separation thickness of the dots is typically about 1 nm to about 3 nm.

There are various ways to construct a solar cell with an up-converter including a quantum dot layer. In one example, the up-converter is electronically separated from the cell itself. In this case, both contacts either need to be located on the light entering side, or the back contact needs to be made transparent and located above the up-conversion layer. FIG. 3 shows an example for an optically isolated up-converting cell with a transparent contact layer, including a quantum dot layer that is electronically isolated from the absorber.

FIG. 3 is a schematic representation of a photovoltaic device 60 including an absorber 62, and an up-converter 64, with an insulating layer 66 between the up-converter and the absorber.

The up-converter layer includes a quantum dot layer 68, which includes a plurality of quantum dots 70 of a semiconductive material. The quantum dots are separated by a wide bandgap semiconductor material or an insulating material 72, such as for example TiO₂ or SiO₂. The quantum dots can be formed on a seedlayer 74, which is supported by a substrate 76, which can be an amorphous metal. The substrate can also serve as a reflector. Underneath the seedlayer is an amorphous layer 92, which is continuous. While in principle the amorphous layer could be the substrate, in practice the amorphous layer 92 is deposited in a separate step.

The absorber includes a p-doped region 78 and an n-doped region 80. These regions can be formed in a material such as silicon. An optional intermediate layer 82 is positioned between the p and n regions. The absorber in this example forms a p-i-n diode. The interface, or junction, between the p and n regions contains an electric field. A transparent conductive oxide (TCO) electrode 84 is formed on top of the absorber. Another electrode TCO 86 is positioned on the opposite side of the p-i-n stack. When light 88 (i.e., photons) hits the device, some of the photons are absorbed in the region of the junction, freeing electrons in the absorber. If the photons have enough energy, the carriers will be driven out by the electric field and move through the absorber and the doped regions and then into an external circuit 90. Photons that pass through the absorber can be up-converted in the up-converter as described above, and directed back into the absorber. In this example, the TCO electrodes serve as means for connecting the device to an external circuit.

Whether or not the quantum dot layer is electronically connected to the active solar cell determines the matrix material into which the quantum dots are embedded. If the quantum dot layer is electronically disconnected from the main solar cell, the function of the matrix material is to separate the dots. TiO₂ and SiO₂ are good examples for matrix materials, as they are known to form good separations between the dots. The same material, e.g., TiO₂ and SiO₂, can be used for the insulator layer between the quantum dot layer and the active solar cell. The insulation layer thickness should be greater than 2 nm, with a typical range of about 5 nm to about 10 nm.

The transparent electrode can be comprised of zinc oxide (ZnO), Al doped ZnO, indium tin oxide (ITO), SnO₂, or fluorinated SnO₂ with preferred thicknesses between about 50 nm and about 200 nm.

In the example of FIG. 1, the up-conversion layer is electronically connected to the main solar cell. In that case, the electrons, which pass through the n-layer adjacent to the quantum dot layer, are injected into the dots. If TiO₂ is chosen as a matrix material, the electrons can also be injected in the TiO₂ and then the electrons can migrate into the contacts. In the example of FIG. 1, the seedlayer and the amorphous metal underneath it form the back contact. It is preferred to have the n-conductor of the photocell adjacent to the back contact. As an electronic connection necessarily creates the additional possibility for the electron-hole pairs to recombine non-radiatively, it is expected that an isolated structure of FIG. 3 may be more efficient. This has to be traded off against an increased series resistance.

The examples described above can be combined with light trapping measures. Light trapping measures include controlled texturing of the bottom reflector to increase the number of paths which the light can make through the absorber, and the up-conversion layer in this case, or controlled roughening of the top surface. Alternatively, plasmon layers can be used to enable multiple passes of the light through the absorber. Additionally, anti-reflection coatings can be applied to the layers.

While the invention has been described in terms of several examples, it will be apparent to those skilled in the art that various changes can be made to the disclosed examples, without departing from the scope of the invention as set forth in the following claims. The implementations described above and other implementations are within the scope of the following claims.

1. A photovoltaic apparatus comprising:
an absorber layer; and
an up-converter layer positioned adjacent to the absorber layer, the up-converter layer including a plurality of quantum dots of first material in a matrix of a second material.

2. The apparatus of claim 1, wherein the first material has a lower bandgap than the absorber layer, and the second material comprises a semiconductive material or an insulator.

3. The apparatus of claim 1, wherein the volume fraction of the quantum dots of the material in the up-converter layer is between about 40% and about 90%.

4. The apparatus of claim 1, wherein the quantum dots form a columnar grain structure.

5. The apparatus of claim 1, wherein the second material comprises one or more of: TiO₂, SiO₂, ZnS, Ta₂O₅, and Nb₂O₅.

6. The apparatus of claim 1, wherein the first material comprise one or more of: PbS, PbSe, InAs, InP, InN, InSb, CdS, CdSe, CdTe, B₂S₃, Bi₂S₃, AlSb, Zn₂P₃, and SiₓGe₁₋ₓ.

7. The apparatus of claim 1, wherein the up-converter layer has a thickness of about 2 nm to about 20 nm.

8. The apparatus of claim 1, wherein the up-converter layer has a thickness of about 2 nm to about 10 nm.

9. The apparatus of claim 1, wherein the absorber layer comprises amorphous SiₓGe₁₋ₓ.

10. The apparatus of claim 1, further comprising:
a substrate layer; and
a seedlayer between the substrate layer and the up-converter layer.

11. The apparatus of claim 10, wherein the seedlayer comprises one or more of: Al, Au, Ag, Pt, Pd, Cu, Ni, Rh, Ru, Co, Re, Os, Cr, Mo, V, Ta, V, and alloys thereof.

12. The apparatus of claim 10, wherein the substrate comprises: FeCoB or CrTa.

13. The apparatus of claim 1, wherein the quantum dots have a size in a range of between about 4 nm and about 12 nm.

14. The apparatus of claim 1, wherein the quantum dots have a thickness in a range of between about 10 nm and about 50 nm.

15. The apparatus of claim 1, wherein the quantum dots are separated from each other by a distance in a range of between about 1 nm and about 3 nm.

16. The apparatus of claim 1, further comprising:
a first electrode electrically connected to the absorber; and
a second electrode electrically connected to the up-converter layer.

17. The apparatus of claim 1, further comprising:
a first electrode electrically connected to a first side of the absorber; and
a second electrode electrically connected to a second side of the absorber.

18. The apparatus of claim 17, wherein the second electrode comprises one or more of: Al doped ZnO, ZnO, ITO, SnO₂ and fluorinated SnO₂.

19. The apparatus of claim 18, wherein the second electrode has a thickness in a range of between about 50 nm and about 500 nm.

20. The apparatus of claim 17, wherein the second electrode comprises one or more of: Al, Au, Ag, Pt, Pd, Cu, Ni, Rh, Ru, Co, and Re.
